(19) United States
(12) Patent Application Publication
(10) Pub. No.: US 2003/0057478 A1
(43) Pub. Date: Mar. 27, 2003

(54) Mos-gated power semiconductor device

(76) Inventors: Chong-man Yun, Seoul (KR); Soo-seong Kim, Seoul (KR); Kyu-hyun Lee, Bucheon-city (KR); Young-chull Kim, Incheon-city (KR)

Correspondence Address: KENNETH E. HORTON, RADER, FISHMAN & GRAUER PLLC, RIVERPARK CORPORATE CENTER ONE, 10653 SOUTH RIVERFRONT PARKWAY, SUITE 150, SOUTH JORDAN, UT, 84095, US

(21) Appl. No.: 10/241,314

(22) Filed: Sep. 10, 2002

(30) Foreign Application Priority Data
Sep. 12, 2001 (KR) 2001-56219

(51) Int. Cl. H01L 29/76; H01L 21/336; H01L 31/113

(52) U.S. Cl. 257/328; 257/329; 438/212; 438/268; 257/341; 257/342

(57) ABSTRACT

A MOS-gated power semiconductor device is described. The MOS-gated power semiconductor device includes a semiconductor substrate that is heavily doped with impurities of a first conductivity type and used as a collector region, a drift region lightly doped with impurities of a second conductivity type on the substrate, a gate insulating layer on the drift region having a center thicker than its edges, a gate electrode on the gate insulating layer, a well region that is lightly doped with impurities of a first conductivity type on the drift region and that has a channel region overlapping a portion of the gate electrode, an emitter region that is heavily doped with impurities of a second conductivity type and that contacts the channel region, an emitter electrode electrically connected to the emitter region and isolated from the gate electrode, and a collector electrode electrically connected to the semiconductor substrate.

FIELD OF THE INVENTION

The invention generally relates to methods for fabricating integrated circuits (ICs) and semiconductor devices and the resulting structures. More particularly, the invention relates to metal oxide semiconductor (MOS) gated power semiconductor devices and methods for making such devices.

BACKGROUND OF THE INVENTION

FIG. 1 depicts a cross-sectional view of an insulated gate bipolar transistor (IGBT), which is one type of a conventional MOS-gated power semiconductor device. As depicted in FIG. 1, a p+ type semiconductor substrate 100 is used as a collector region. On the p+ type semiconductor substrate 100 are sequentially located an n+ type buffer layer 110 and an n− type drift region 120. A p− type well region 130 is located on the n− type drift region 120. As well, n+ type emitter regions 140 are located on the p− type well region 130.

Still referring to FIG. 1, a gate electrode 160 with a gate insulating layer 150 at its bottom is located on portions of the n− type drift region 120 and the p− type well regions 130. Channels are located at portions of the p− type well regions 130 that overlap the gate electrode 160 when predetermined conditions are satisfied. An emitter electrode 170 contacts some surfaces of the n+ type emitter regions 140, and is electrically isolated from the gate electrode 160 by an insulating layer 180. Although not illustrated in the drawings, a collector electrode can be located at the rear or bottom portion of the p+ type semiconductor substrate 100.

With the above structure, the ON-resistance Rₒₙ may be represented as the total of the substrate resistance R_{sub}, the channel resistance R_{ch}, the accumulated resistance R_{acc}, the junction field effect transistor (JFET) region resistance R_{jfet}, and the drift region resistance R_{drift}. In certain instances, the emitter resistance and the contact resistance may be included in calculating the Rₒₙ.

As with other semiconductor devices, the industry is always trying to decrease the size of the devices, such as the size of the gate electrode. A reduction in the length of the gate electrode 160, however, results in an increase in the JFET region resistance R_{jfet} and a corresponding increase in the On-resistance Rₒₙ of a device. To lower the On-resistance Rₒₙ when reducing the length of the gate electrode 160, it has been suggested to increase the concentration of impurities in the drift region 120. Although JFET region resistance R_{jfet} can be lowered by this suggestion, a depletion region is deformed when applying bias in the reverse direction and reduces the breakdown voltage of the device. Further, parasitic capacitance components can be increased when implementing this suggestion, thereby reducing the switching speed of the device.

SUMMARY OF THE INVENTION

The invention includes a MOS-gated power semiconductor device in which breakdown voltage is not reduced, the parasitic capacitance is not increased, and the On-resistance is reduced.

The invention also includes a MOS-gated power semiconductor device containing: a semiconductor substrate that is heavily doped with impurities of a first conductivity type and that is used as a collector region; a drift region lightly doped with impurities of a second conductivity type on the semiconductor substrate; a gate insulating layer on the drift region and whose center is comparatively thicker than its edges; a gate electrode on the gate insulating layer; a well region that is lightly doped with impurities of a first conductivity type on the drift region and that has a channel region that is overlapped with a portion of the gate electrode; an emitter region that is heavily doped with impurities of a second conductivity type and that contacts the channel region; an emitter electrode electrically connected with the emitter region and isolated from the gate electrode; and a collector electrode electrically connected to the semiconductor substrate.

In one aspect of the invention, a first portion of the drift region contacts a portion of the gate insulating layer with a relatively thin thickness. This first portion is more heavily doped with impurities than a second portion of the drift region that contacts a portion of the gate insulating layer having a relatively thick thickness.

In another aspect of the invention, the device further includes a buffer layer that is heavily doped with impurities of a second conductivity type. The buffer layer may be located between the semiconductor substrate and the drift region. In still another aspect of the invention, the first conductivity type is p type and the second conductivity type is n type.

The invention further includes a MOS-gated power semiconductor device containing: a semiconductor substrate that is heavily doped with impurities of a first conductivity type and that is used as a collector region; a drift region lightly doped with impurities of a first conductivity type on the semiconductor substrate; a gate insulating layer on the drift region and with a center that is comparatively thicker than its edges; a gate electrode on the gate insulating layer; a well region lightly doped with impurities of a second conductivity type on the drift region, the well region having a channel region that overlaps a portion of the gate electrode; a source region that is heavily doped with impurities of a first conductivity type and overlaps the channel region; a source electrode electrically connected with the source region and isolated from the gate electrode; and a drain electrode electrically connected with the semiconductor substrate.

In one aspect of the invention, a first portion of the drift region contacts a portion of the gate insulating layer with a relatively thin thickness. This first portion is more heavily doped with impurities than a second portion of the drift region that contacts a portion of the gate insulating layer having a relatively thick thickness.

In another aspect of the invention, the first conductivity type is n type and the second conductivity type is p type.

### BRIEF DESCRIPTION OF THE DRAWINGS

FIGS. 1-10 are views of one aspect of the MOS-gated power semiconductor devices and methods of making such devices according to the invention, in which:

FIG. 1 is a cross-sectional view of a conventional MOS-gated power semiconductor device;

FIG. 2 is a cross-sectional view of a MOS-gated power semiconductor device according to one aspect of the invention;

FIG. 3 is a cross-sectional view of a MOS-gated power semiconductor device according to another aspect of the present invention;

FIG. 4 is a graph comparing the parasitic capacitance of a MOS-gated power semiconductor device according to the invention with that of a conventional MOS-gated power semiconductor device;

FIGS. 5 through 9 are cross-sectional views for explaining a method for fabricating a MOS-gated power semiconductor device according to the invention; and

FIG. 10 is a cross-sectional view for explaining optional steps that may be needed to fabricate a MOS-gated power semiconductor device according to the invention.

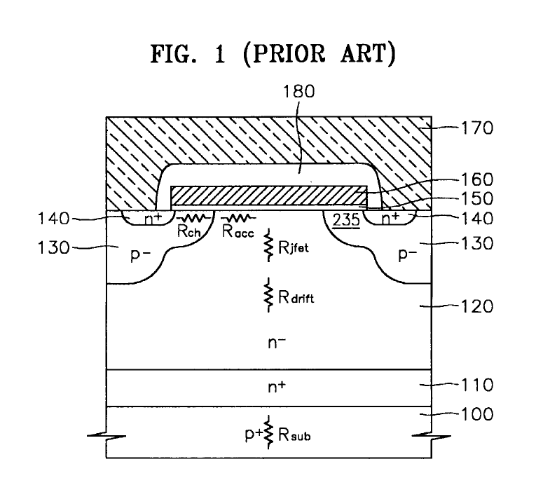

FIGS. 1-10 presented in conjunction with this description are views of only particular-rather than complete-portions of the MOS-gated power semiconductor devices and methods of making such devices according to the invention. Together with the following description, the Figures demonstrate and explain the principles of the invention.

DETAILED DESCRIPTION OF THE INVENTION

The invention now will be described more fully with reference to the accompanying drawings, in which preferred aspects of the invention are shown. This invention may, however, be embodied in many different forms and should not be construed as being limited to the aspects set forth herein. Rather, these aspects are provided so that this disclosure will be thorough and complete, and will fully convey the concept of the invention to those skilled in the art. In the drawings, the thickness of layers and regions are exaggerated for clarity. It will also be understood that when a layer is referred to as being “on” another layer or substrate, it can be directly on the other layer or substrate, or intervening layers may also be present. The same reference numerals in different drawings represent the same element, and thus their description will be omitted.

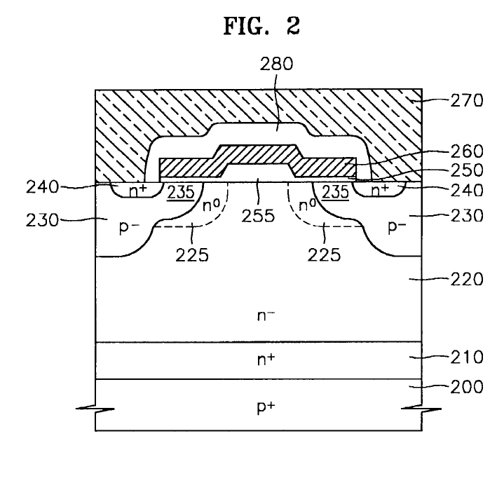

FIG. 2 is a cross-sectional view of MOS-gated power semiconductor device in one aspect of the invention. In this aspect of the invention, the MOS-gated power semiconductor device is an insulated gate bipolar transistor (IGBT). Referring to FIG. 2, a p+ type semiconductor substrate 200 is used as a collector region. On the p+ type semiconductor substrate 200 are sequentially located an n+ type buffer layer 210 and an n− type drift region 220. The n− type drift region 220 includes n⁰− type drift regions 225 that are relatively heavily doped with impurities of the same conductivity type. P− type well regions 230, which can be used as a base region, are located on the n− type drift region 220. As well, n+ type emitter regions 240 are located on the p− type well regions 230.

A gate insulating layer 250 is located under gate electrode 260. The gate electrode 260 (and, therefore, the gate insulating layer 250) overlaps portions of the n− type drift region 220 and of the p− type well regions 230. Portions of the upper surfaces of the p− type well regions 230 that overlap the gate electrode 260 are channel regions 235.

Inversion layers can form in channel regions 235 when a predetermined voltage is applied to the gate electrode 260.

The gate insulating layer 250 includes, at its center, a protrusion 255 whose thickness is thicker than the edge portions of the gate insulating layer 250. In more detail, the edge portions of the gate insulating layer 250 are relatively thin on the channel regions 235 and n⁰ type drift regions 225. The central portion of the gate insulating layer 250 (i.e., the protrusion 255), however, is relatively thicker on the n− type drift region 220 between the n⁰ type drift regions 225.

An emitter electrode 270 contacts the portions of the surface of the n+ type emitter regions 240 and is electrically isolated from the gate electrode 260 by an insulating layer 280. Although not illustrated in the drawings, a collector electrode can be electrically connected with the rear or bottom portion of the p+ type semiconductor substrate 200.

In the device of FIG. 2, it is possible to reduce the On-resistance Rₒₙ without reducing its breakdown voltage. This result can be obtained by defining the n⁰ type drift regions 225, which are relatively highly doped with impurities, at selected portions of the n− type drift region 220. This result can also be obtained because the gate insulating layer 250 contains the protrusion 255 with a relatively larger thickness, thereby reducing the size of the parasitic capacitance.

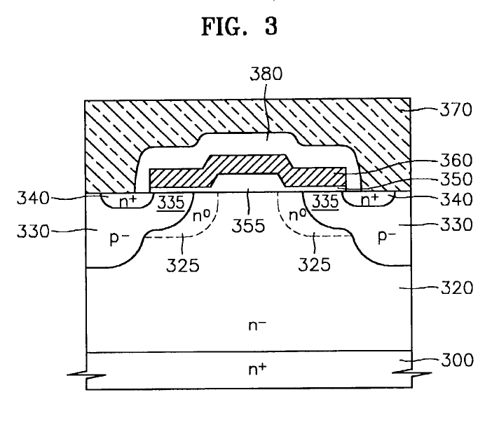

FIG. 3 depicts another aspect of the MOS-gated power semiconductor devices of the invention. In this aspect of the invention, the device is MOS field-effect transistor (MOSFET) semiconductor device. Referring to FIG. 3, an n− type drift region 320 is located on an n+ type semiconductor substrate 300, unlike the device of FIG. 2. The n+ type semiconductor substrate 300 is used as a drain region. The n− type drift region 320 includes an n⁰ type drift region 325 of the same conductivity type as the n− type drift region 320, but is more heavily doped with these impurities. A p− type well region 330 is located on the n− type drift region 320 and a n+ type source region 340 is located on the p− type well region 330.

A gate insulating layer 350 is located under a gate electrode 360. The gate electrode 360 (and, therefore the gate insulating layer 350) is located on portions of the n− type drift region 320 and portions of the p− type well regions 330. The upper portions of the p− type well region 330, which overlap the gate electrode 360, are channel regions 335 in which inversion layers can be formed when a selected voltage is applied to the gate electrode 360.

The gate insulating layer 350 includes a protrusion 355 whose thickness is greater at the center than at the edge portions. In more detail, the edge portions of the gate insulating layer 350 are relatively thin on the channel regions 335 and n⁰ type drift regions 325. The central portion of the gate insulating 350 (i.e., the protrusion 355), however, is relatively thicker on the n− type drift region 320 between the n⁰ type drift regions 325.

A source electrode 370 contacts portions of the n+ type source regions 340 and is electrically isolated from the gate electrode 360 by an insulating layer 380. Although not illustrated in FIG. 3, a drain electrode can be electrically connected with the n+ type semiconductor substrate 300 at the rear or bottom face of the n+ type semiconductor substrate 300.

In the device of FIG. 3, the n⁰ type drift regions 325 are defined within predetermined regions of the n− type drift region 320. As well, the gate insulating layer 350 is thicker at the center than at the edges. Thus, the device of FIG. 3 has a similar structure as the device of FIG. 2 and, therefore, has similar properties as those described above.

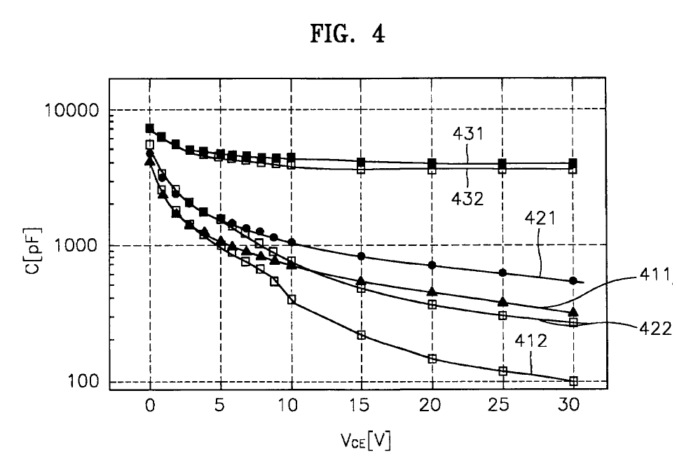

FIG. 4 is a graph illustrating the parasitic capacitance of a MOS-gated power semiconductor device according to the invention relative to that capacitance exhibited by a conventional MOS-gated power semiconductor device. In FIG. 4, the horizontal axis denotes the voltage V_{CE} between collectors and emitters and the vertical axis denotes the parasitic capacitance C. From FIG. 4, it can be noted that the parasitic capacitances 412, 422, and 432 in the IGBT of FIG. 2 are smaller than the parasitic capacitances 411, 421, and 431 of a conventional IGBT. In FIG. 4, reference numerals 412 and 411 denote the capacitance C_{gc} between a gate and a collector. Reference numerals 422 and 421 denote the capacitance C_{ce} between a collector and emitter and the capacitance C_{gc} between a gate and collector. Reference numerals 432 and 431 denote the sum of the capacitance C_{ge} between the gate and emitter and the capacitance C_{gc} between the gate and the collector, respectively.

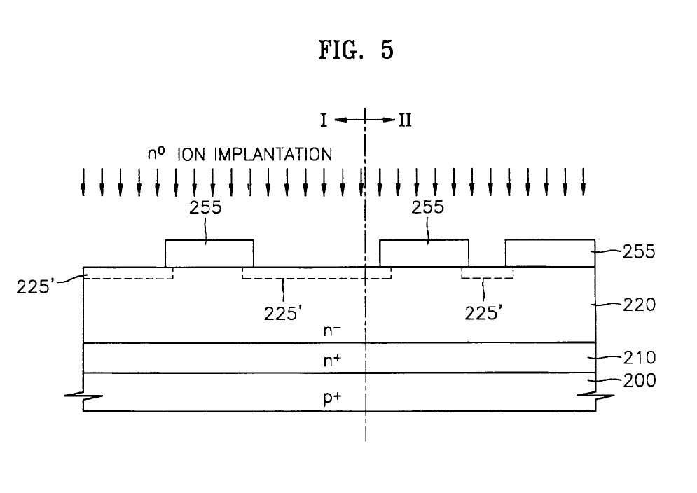

FIGS. 5 through 9 are cross-sectional views used in explaining a method of fabricating a MOS-gated power semiconductor device according to the invention. In these Figures, the region left of the dotted line indicates an active region I and the region right of the dotted line indicates a ring region II.

Referring to FIG. 5, an n+ type buffer layer 210 is first formed on a p+ type semiconductor substrate 200. Then, an n− type drift region 220 is formed on the n+ type buffer layer 210 by an epitaxial growth process. Next, an oxide layer pattern 255 is formed on selected portions of the active region I and the ring region II. Thereafter, n⁰ type impurity ions are implanted into the resulting structure using the oxide layer pattern 255 as an ion implantation mask. Thus, n⁰ type impurity regions 225′ are formed in the active region I and the ring region II.

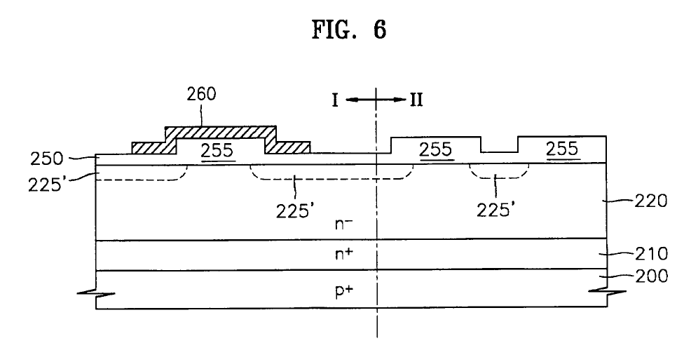

As shown in FIG. 6, a thin gate oxide layer (not shown) is then formed on the n− type drift region 220 by an oxidization process. Together with the oxide layer patterns 255, this gate oxide layer will form gate insulating layer 250, the center and edges of which are formed to a different thickness. Then, a conductive layer, e.g., a polysilicon layer, is formed and patterned to form a gate electrode 260 that covers the gate insulating layer 250 in the active region I.

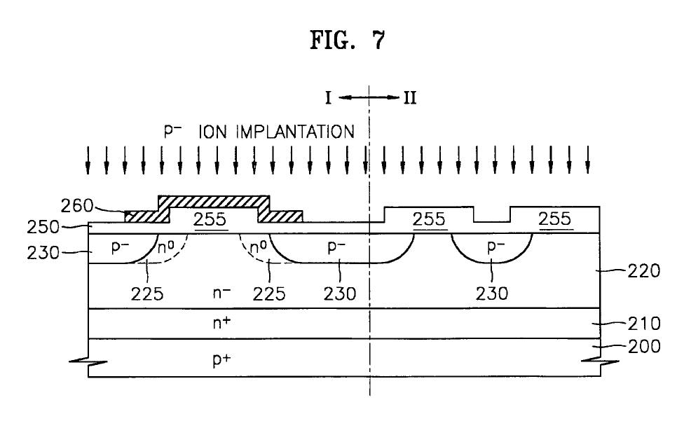

As shown in FIG. 7, a process of implanting p− type impurity ions is performed on the resulting structure using the gate electrode 260 as an ion implantation mask. Then, a drive-in diffusion process is performed to form p− type well regions 230 in the active region I and the ring region II. At this point, the n⁰ type impurity ions (which are implanted during the previous process) are also diffused to make the n⁰ type drift regions 225 adjacent to the p− type well regions 230.

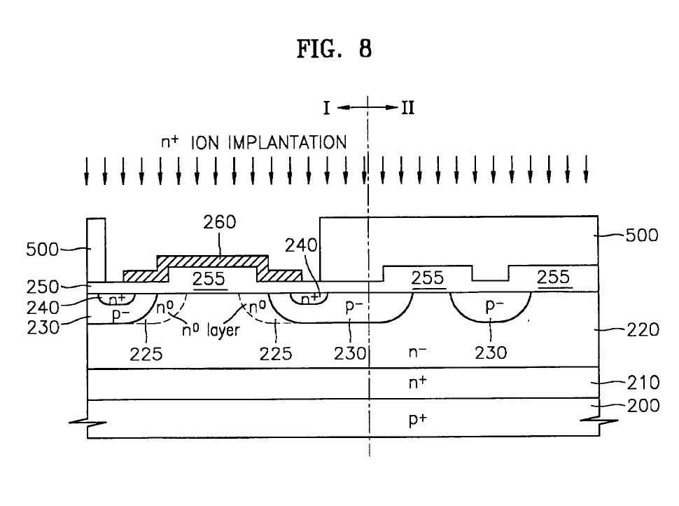

As depicted in FIG. 8, a mask layer pattern 500 is then formed. This pattern 500 exposes a portion of the gate insulating layer 250 formed in the active region I but covers the upper portion of the ring region II completely. In one aspect of the invention, the mask layer pattern 500 may be a photoresist layer pattern. Then, n+ type impurity ions are implanted into the resulting structure using the mask layer pattern 500 as an ion implantation mask. Then, the implanted n+ type impurity ions are diffused to form n+ type emitter regions 240 on the p− type well regions 230 in the active region I. The mask layer pattern 500 is then removed.

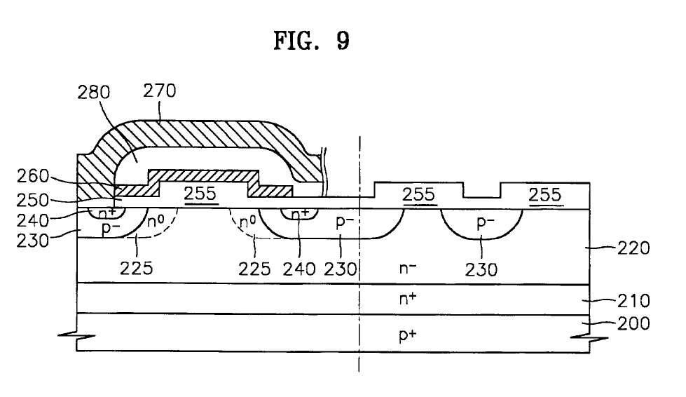

As shown in FIG. 9, an insulating layer 280 is formed to cover the gate electrode 260 on the active region I and then patterned to expose a portion of the p− type well region 230 and a portion of the n+ type emitter region 240. Next, a metal layer (not shown) is formed to entirely cover the resulting structure, thereby forming an emitter electrode 270 in contact with the n+ type emitter region 240. Next, although not illustrated on the drawings, a collector electrode can be formed at the rear side of the p+ type semiconductor substrate 200.

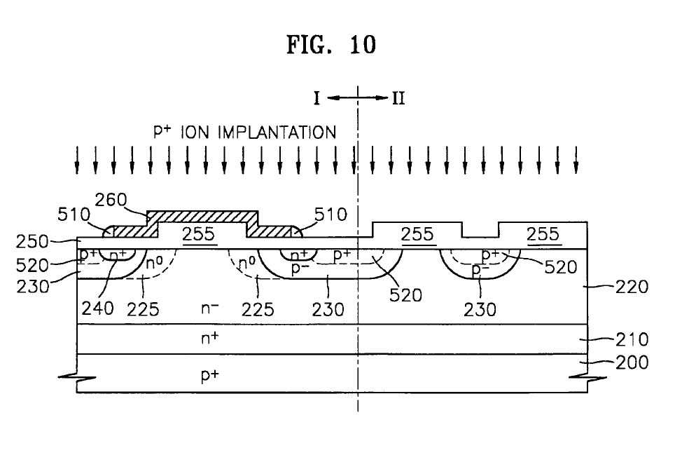

In one aspect of the invention, and as illustrated in FIG. 10, additional steps can be added when performing a method of fabricating a MOS-gated power semiconductor substrate. For example, it is possible to perform processes for forming gate spacers along both sides of the gate electrode 260 and processes for forming n+ type impurity regions for high ruggedness in the p− type well regions 230.

As depicted in FIG. 10, gate spacers 510 are formed along both sides of the gate electrode 260 by a conventional method after performing the processes illustrated in FIGS. 5 through 8. Next, n+ type impurity ions are implanted into the resulting structure using the gate electrode 260, the gate spacers 510, and the thick center of the gate insulating layer 250 as an ion implantation mask. Then, a drive-in diffusion process is performed to make p+ type impurity regions 520 for high ruggedness on the p− type well regions 230. Thereafter, the subsequent processes explained in FIG. 9 are then performed.

The above method is used to fabricating an IGBT device, which is one type of MOS-gated power semiconductor devices. In another aspect of the invention, a MOSFET device can be also fabricated using a similar method but by using a n+ type semiconductor substrate rather than a p+ type semiconductor substrate.

As described above, a MOS-gated power semiconductor device of the invention contains a drift region, which is heavily doped with impurities, on an upper portion of a drift region in contact with a well region. Further, the MOS-gated power semiconductor device of the invention contains a gate insulating layer that is thick over a drift region that is lightly doped with impurities. Using these features, the On-resistance of the devices of the invention can be reduced without reducing its breakdown voltage, and the parasitic capacitance of device can be reduced.

Having described these aspects of the invention, it is understood that the invention defined by the appended claims is not to be limited by particular details set forth in the above description, as many apparent variations thereof are possible without departing from the spirit or scope thereof.

We claim:

1. A MOS-gated power semiconductor device comprising:
a semiconductor substrate heavily doped with impurities of a first conductivity type, the semiconductor substrate being used as a collector region;
a drift region lightly doped with impurities of a second conductivity type on the semiconductor substrate;
a gate insulating layer formed on the drift region, the gate insulating layer whose center is comparatively thicker than its edges;
a gate electrode formed on the gate insulating layer;
a well region lightly doped with impurities of a first conductivity type on the drift region, the well region having a channel region that is overlapped with a portion of the gate electrode;
an emitter region heavily doped with impurities of a second conductivity type, the emitter region formed to be in contact with the channel region;
an emitter electrode being electrically connected with the emitter region, the emitter electrode being isolated from the gate electrode; and
a collector electrode being electrically connected with the semiconductor substrate.

2. The device of claim 1, wherein a portion of the drift region, which is in contact with a portion of the gate insulating layer having a comparative thin thickness, is more heavily doped with impurities than a portion of the drift region, which is in contact with a portion of the gate insulating layer having a comparative thick thickness.

3. The device of claim 1 further comprising a buffer layer that is heavily doped with impurities of a second conductivity type between the semiconductor substrate and the drift region.

4. The device of claim 1, wherein the first conductivity type is p type, and the second conductivity type is n type.

5. A MOS-gated power semiconductor device comprising:
a semiconductor substrate heavily doped with impurities of a first conductivity type, the semiconductor substrate being used as a collector region;
a drift region lightly doped with impurities of a first conductivity type on the semiconductor substrate;
a gate insulating layer formed on the drift region, the gate insulating layer whose center is comparatively thicker than its edges;
a gate electrode being formed on the gate insulating layer;
a well region lightly doped with impurities of a second conductivity type formed on the drift region, the well region having a channel region that is overlapped with a portion of the gate electrode;
a source region heavily doped with impurities of a first conductivity type, the source region formed to be overlapped with the channel region;
a source electrode being electrically connected with the source region, the source electrode isolated from the gate electrode; and
a drain electrode electrically connected with the semiconductor substrate.

6. The device of claim 5, wherein a portion of the drift region, which is in contact with a portion of the gate insulating layer having a comparative thin thickness, is more heavily doped with impurities than a portion of the drift region, which is in contact with a portion of the gate insulating layer having a comparative thick thickness.

7. The device of claim 5, wherein the first conductivity type is n type, and the second conductivity type is p type.

8. A MOS-gated power semiconductor structure, comprising:
a drift region lightly doped with impurities of a first conductivity type;
a gate insulating layer on the drift region, the gate insulating layer having a center thicker than its edges;
a gate electrode on the gate insulating layer;
a well region lightly doped with impurities of a second conductivity type on the drift region, the well region having a channel region overlapping a portion of the gate electrode;
a source region heavily doped with impurities of a first conductivity type, the source region overlapping the channel region; and
a source electrode electrically connected to the source region, the source electrode isolated from the gate electrode.

9. A semiconductor device containing a MOS-gated power semiconductor structure, the structure comprising:
a drift region lightly doped with impurities of a first conductivity type;
a gate insulating layer on the drift region, the gate insulating layer having a center thicker than its edges;
a gate electrode on the gate insulating layer;
a well region lightly doped with impurities of a second conductivity type on the drift region, the well region having a channel region overlapping a portion of the gate electrode;
a source region heavily doped with impurities of a first conductivity type, the source region overlapping the channel region; and
a source electrode electrically connected to the source region, the source electrode isolated from the gate electrode.

10. A MOS-gated power semiconductor structure, comprising:
a drift region lightly doped with impurities of a first conductivity type;
a gate insulating layer on the drift region, the gate insulating layer having a center thicker than its edges;
a gate electrode on the gate insulating layer; and
a well region lightly doped with impurities of a second conductivity type on the drift region, the well region having a channel region overlapping a portion of the gate electrode.

11. A semiconductor device containing a MOS-gated power semiconductor structure, the structure comprising:
a drift region lightly doped with impurities of a first conductivity type;
a gate insulating layer on the drift region, the gate insulating layer having a center thicker than its edges;
a gate electrode on the gate insulating layer; and
a well region lightly doped with impurities of a second conductivity type on the drift region, the well region having a channel region overlapping a portion of the gate electrode.

12. A method for making a MOS-gated power semiconductor structure, the method comprising:
providing a drift region lightly doped with impurities of a first conductivity type;
providing a gate insulating layer on the drift region, the gate insulating layer having a center thicker than its edges;
providing a gate electrode on the gate insulating layer;
providing a well region lightly doped with impurities of a second conductivity type on the drift region, the well region having a channel region overlapping a portion of the gate electrode;
providing a source region heavily doped with impurities of a first conductivity type, the source region overlapping the channel region; and
providing a source electrode electrically connected to the source region, the source electrode isolated from the gate electrode.

13. A method for making a MOS-gated power semiconductor structure, the method comprising:
providing a drift region lightly doped with impurities of a first conductivity type;
providing a gate insulating layer formed on the drift region, the gate insulating layer having a center thicker than its edges;
providing a gate electrode on the gate insulating layer; and
providing a well region lightly doped with impurities of a second conductivity type on the drift region, the well region having a channel region overlapping a portion of the gate electrode.

14. A MOS-gated power semiconductor structure, comprising:
a semiconducting region containing a second dopant region on a first dopant region, wherein the first dopant region comprises a first conductivity type and the second dopant region comprises a second conductivity type and has a channel region; and
a gate structure on a portion the semiconducting region, wherein the gate structure overlaps the channel region and wherein the gate structure contains a gate insulating layer having a center thicker than its edges.

15. A semiconductor device containing a MOS-gated power semiconductor structure, the structure comprising:
a semiconducting region containing a second dopant region on a first dopant region, wherein the first dopant region comprises a first conductivity type and the second dopant region comprises a second conductivity type and has a channel region; and
a gate structure on a portion the semiconducting region, wherein the gate structure overlaps the channel region and wherein the gate structure contains a gate insulating layer having a center thicker than its edges.

16. A method for making a MOS-gated power semiconductor structure, the method comprising:
providing a semiconducting region containing a second dopant region on a first dopant region, wherein the first dopant region comprises a first conductivity type and the second dopant region comprises a second conductivity type and has a channel region; and
providing a gate structure on a portion the semiconducting region, wherein the gate structure overlaps the channel region and wherein the gate structure contains a gate insulating layer having a center thicker than its edges.

17. A method for making a MOS-gated power semiconductor structure, the method comprising:
providing a substrate;
providing a drift region over the substrate;
providing a well region on the drift region, the well region containing a channel region;
providing a gate structure overlapping the channel region, wherein the gate structure contains a gate insulating layer having a center thicker than its edges.

18. The method of claim 17, wherein the substrate comprises a semiconducting material that has been doped with a first conductivity type dopant.

19. The method of claim 17, including lightly doping the drift region with a dopant of a second conductivity type.

20. The method of claim 17, including lightly doping the well region with a dopant of a first conductivity type.

21. The method of claim 17, wherein the gate structure comprises a gate electrode on the gate insulating layer.

22. The method of claim 21, further including providing the gate structure by forming a gate insulating layer and then forming the gate electrode on the gate insulating layer.

23. The method of claim 21, further including forming an emitter region heavily doped with a second conductivity type dopant to contact the channel region.

24. The method of claim 23, further including forming an emitter electrode to electrically connect with the emitter region yet be isolated from the gate electrode; and

25. The method of claim 17, further including forming a collector electrode to be electrically connected with the semiconductor substrate.
